(19) United States
(12) Patent Application Publication
(10) Pub. No.: US 2006/0255836 A1
(43) Pub. Date: Nov. 16, 2006

(54) Clock driver circuit and driving method therefor

(76) Inventor: Rikikazu Ikeda, Tokyo (JP)

Correspondence Address: MICHAEL BEST & FRIEDRICH LLP, Two Prudential Plaza, 180 North Stetson Avenue, Suite 2000, CHICAGO, IL, 60601, US

(21) Appl. No.: 11/395,506

(22) Filed: Mar. 31, 2006

(30) Foreign Application Priority Data
Mar. 31, 2005 (JP) 2005-101432

(51) Int. Cl. H03K 19/094

(52) U.S. Cl. 326/83

(57) ABSTRACT

A clock driver circuit has a plurality of driver circuits 20, 30 connected in parallel with each other, and a control circuit 40 for stopping the operation of a part of the plurality of driver circuits for a given period of time, based on at least one of a rise and a fall of an input signal. From the rising/falling edges of the input signal until a predetermined time lapses, all of the driver circuits 20, 30 operate in parallel concurrently to thereby exhibit a high driving capability. Subsequently, the part of the drivers stops the operation during a transient period of an output waveform to thereby prevent the overshoot/undershoot. Therefore, overshoot/undershoot is prevented while a higher driving capability is realized.

This application claims priority to prior Japanese patent application JP 2005-101432, filed Mar. 31, 2005, the disclosure of which is incorporated herein by reference.

### BACKGROUND OF THE INVENTION

1. Field of the Invention

The present invention relates to a clock driver circuit and a driving method thereof and, in particular, it relates to a clock driver circuit that has a plurality of driver circuits of the same configuration both of which are connected in parallel with each other, and a driving method thereof.

2. Description of the Related Art

With an increase in the clock frequency of a semiconductor integrated circuit, it is required for a clock driver circuit to have a high driving capability (di/dt: current per unit time). In order to meet this requirement, a conventional clock driver circuit has a configuration such that a plurality of driver circuits 81 and 82 of the same circuitry are connected in parallel with each other, as shown in FIG. 8.

Herein, it is also noted that, as another prior art example of the clock driver circuit which has a plurality of driver circuits connected in parallel with each other, proposal is made about a circuit which is configured so that the driving capability is changed in accordance with a load (for example, see Japanese Unexamined Patent Publication (JP-A) No. 02-187811).

Moreover, proposal has been also made about suppressing overshoot and undershoot in a driver circuit composed of a CMOS inverter. Specifically, there has been known a technology of driving a PMOS transistor and an NMOS transistor by driving signals which have waveforms different from each other (for example, see Japanese Unexamined Patent Publication (JP-A) No. 05-227003).

### SUMMARY OF THE INVENTION

A conventional clock driver circuit has a plurality of driver circuits which are connected in parallel with each other and which perform the same operations. As a result, the conventional clock driver circuit has a problem such that the overshoot and/or the undershoot are caused to occur in output signals of the driver circuits and are included in an output signal when the driving capability becomes high.

The overshoot or undershoot included in the output of the clock driver circuit acts as a noise or a noise source for the semiconductor integrated circuit that receives the output of the clock driver circuit, and possibly causes a malfunction of an element. In addition, a large amount of overshoot or undershoot may degrade or even damage the element. Anyhow, the overshoot or undershoot included in the output of the clock driver circuit may decrease reliability of the semiconductor integrated circuit connected to the following stage thereof.

Moreover, in the clock driver circuit described in the foregoing Japanese Unexamined Patent Publication No. 02-187811, the overshoot or undershoot may be prevented by decreasing the driving capability in accordance with the load. However, there is a problem that the overshoot or undershoot cannot be prevented while the driving capability is being kept high.

Furthermore, the driver circuit described in the foregoing Japanese Unexamined Patent Publication (JP-A) No. 05-227003, is disadvantageous in that a sufficient output cannot be provided on a rise of the output, so that a high driving capability cannot be obtained.

Therefore, the object of the present invention is to provide a clock driver circuit and a driving method thereof which can prevent occurrence of the overshoot and/or undershoot, without substantially decreasing the driving capability, by using a plurality of driver circuits connected in parallel with each other.

In order to achieve the foregoing object, the present invention provides a clock driver circuit comprising a plurality of driver circuits connected in parallel with each other, and a control circuit for stopping the operation of a part of the plurality of driver circuits for a given period of time, in response to at least one of a rising edge and a falling edge of an input signal.

Moreover, the present invention also provides a driving method of the clock driver circuit in which the plurality of driver circuits connected in parallel with each other. The method comprises stopping the operation of a part of the plurality of driver circuits for a given period of time, in response to at least one of the rising edge and the falling edge of the input signal.

According to the present invention, the control circuit is provided so as to stop the operation of a part of the plurality of driver circuits connected in parallel for the given period of time, in response to at least one of the rising edge and the falling edge of the input signal. The clock driver circuit can prevent the overshoot and/or undershoot with the high driving capability kept.

Moreover, according to the present invention, by stopping the operation of a part of the plurality of driver circuits connected in parallel for the given period of time, in response to at least one of the rising edge and the falling edge of the input signal, there is obtained the driving method of the clock driver circuit which can prevent the overshoot and/or undershoot with the high driving capability kept.

### BRIEF DESCRIPTION OF THE DRAWINGS

FIG. 1 is a block diagram illustrating a principle configuration of a clock driver circuit according to the present invention;

FIG. 2 is a circuit diagram illustrating a configuration of a clock driver circuit according to a first embodiment of the present invention;

FIG. 3 is a circuit diagram illustrating a configuration example of the first control circuit used for the clock driver circuit in FIG. 2;

FIG. 4 is a signal waveform diagram for describing an operation of the clock driver circuit in FIG. 2;

FIG. 5 is a circuit diagram illustrating a configuration of a clock driver circuit according to a second embodiment of the present invention;

FIG. 6 is a circuit diagram illustrating a configuration example of a second control circuit used for the clock driver circuit in FIG. 5;

FIG. 7 is a signal waveform diagram for describing an operation of the clock driver circuit in FIG. 5; and

FIG. 8 is a circuit diagram illustrating a configuration of a conventional clock driver circuit.

### DESCRIPTION OF THE PREFERRED EMBODIMENTS

Next, preferred embodiments of the present invention will be described in detail by referring to the drawings.

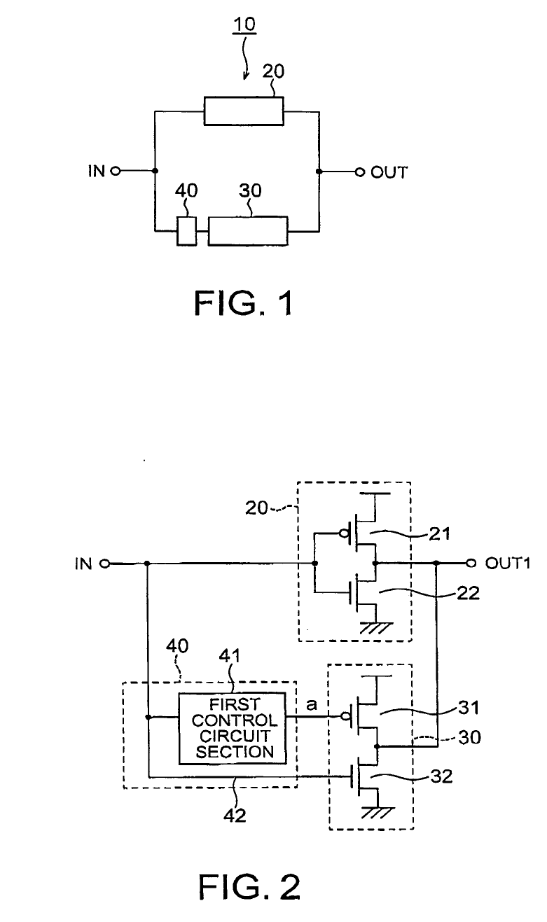

FIG. 1 illustrates a principle configuration of a clock driver circuit according to the present invention. The clock driver circuit 10 comprises a plurality (herein, two) of driver circuits 20 and 30, which have the same configuration and are connected in parallel with each other, and a control circuit 40 connected between an input terminal IN and a part (herein, one) of the driver circuits 30. Both the driver circuits 20 and 30 are connected in an output terminal OUT of the clock driver circuit, as illustrated in FIG. 1.

The driver circuit 20 generates an output signal (low level or high level) in accordance with an input clock signal supplied to the input terminal IN.

The driver circuit 30 has the same configuration as that of the driver circuit 20, and generates the same output signal as that of the driver circuit 20, when the input clock signal supplied to the input terminal IN is directly inputted thereto. In the present embodiment, however, the driver circuit 30 is supplied with the output of the control circuit 40 which produces, as a driving signal, an output signal different from that of the driver circuit 20.

The control circuit 40 receives the input clock signal through the input terminal IN and generates a driving signal for driving the driver circuit 30. The driving signal serves to stop the operation of the driver circuit 30 for a given period of time T1, in response to at least one of a rising edge and a falling edge of the input clock signal.

Specifically, the control circuit 40 drives the driver circuit 30 in a manner similar to the driver circuit 20 for a predetermined time T2 in response to a rising/falling edge of the input clock signal. Subsequently, the driving circuit 40 again stops the operation of the driver circuit 30 after lapse of the predetermined time until reception of the next rising/falling edge of the input clock signal.

More specifically, in the case of preventing the overshoot, the control circuit 40 changes the output of the driver circuit 30 from a low level to a high level when the output of the driver circuit 20 is changed from the low level to the high level (for example, in response to the falling of the input clock signal). The control circuit 40 then stops the operation of the driver circuit 30 for the given period of time T1 after the predetermined time T2 lapses and before the output of the driver circuit 20 becomes the high level.

In addition, in the case of preventing the undershoot, the control circuit 40 changes the output of the driver circuit 30 from the high level to the low level when the output of the driver circuit 20 is changed from the high level to the low level (for example, in response to the rising edge of the input clock signal). The control circuit 40 then stops the operation of the driver circuit 30 for a given period of time T1 after the predetermined time T2 lapses and before the output of the driver circuit 20 becomes the low level.

As described above, according to the present embodiment, it is possible to prevent occurrence of the overshoot/undershoot in the output of the clock driver circuit. Thus, the illustrated circuit makes it possible to maintain the reliability of the semiconductor integrated circuit connected to the following stage of the clock driver circuit. With this structure, one of the driver circuits, namely, 20 alone is put into an active state before occurrence of the overshoot and/or the undershoot while another one of the driver circuits, namely, 30 is put into an inactive state before the occurrence of the overshoot and/or the undershoot. Therefore, this structure is effective to avoid the occurrence of the overshoot and/or the undershoot.

Next, a first embodiment of the present invention will be described by referring to FIGS. 2 through 4.

As shown in FIG. 2, in the clock driver circuit of the present embodiment, the driver circuits 20 and 30 are implemented by CMOS inverters each of which is composed of a pair of PMOS and NMOS transistors 21 and 22 and another pair of PMOS and NMOS transistors 31 and 32.

The illustrated driver circuit 20 is directly connected to the input terminal IN and the output terminal OUT and consistently generates the output signal in accordance with the input clock signal. The driver circuit 20 will be hereinafter referred to as a main clock driver circuit.

In addition, the driver circuit 30 is connected to the output terminal OUT in parallel with the driver circuit 20 and is also connected at its input terminal (a) to the control circuit 40. The driver circuit 30 will be hereinafter referred to as a sub-clock driver circuit.

The illustrated control circuit 40 has a first control circuit section 41 and a branch line 42. The first control circuit section 41 is connected between the input terminal IN and a gate of the PMOS transistor 31 in the driver circuit 30, while the branch line 42 is connected between the input terminal IN and a gate of the NMOS transistor 32 in the driver circuit 30.

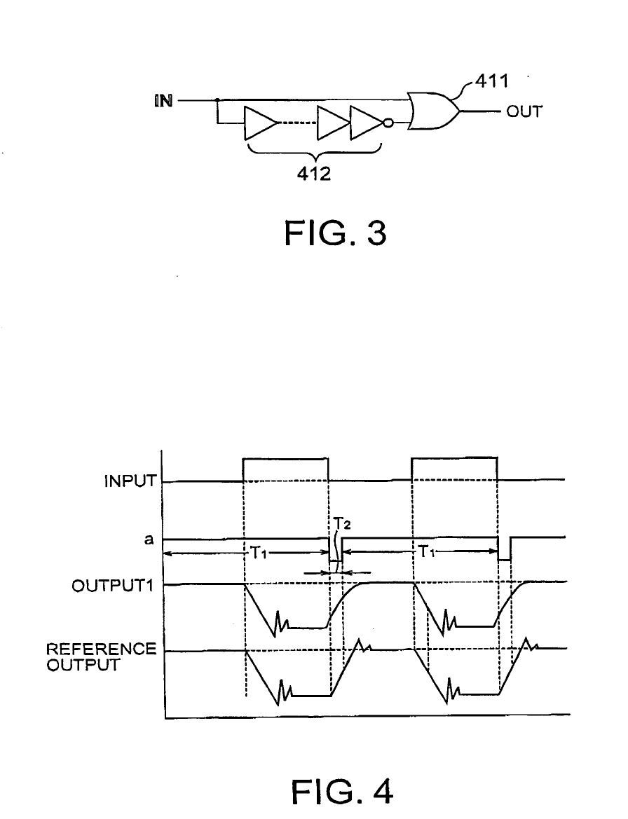

The first control circuit section 41 is composed of a two-input OR gate 411, and a delay circuit 412 which is composed of a plurality of stages of delay gates and an NOT gate, as shown in, for example, FIG. 3.

Next, description will be made about the operation of the clock driver circuit in FIG. 2.

Since the main driver circuit 20 is directly supplied with the input clock signal, it performs ordinary inverter operation. Namely, when the input clock signal takes the high level, the PMOS transistor 21 is put in an off-state and the NMOS transistor 22 is put in on-state, so that the main driver circuit 20 outputs the low level signal. Meanwhile, when the input clock signal takes the low level, the PMOS transistor 21 is put in on-state and the NMOS transistor 22 is put in off-state, so that the main driver circuit 20 outputs the high level signal.

In the manner described above, the output of the main driver circuit 20 is changed from the low level to the high level when the input clock signal is changed from the high level to the low level. On the other hand, the output of the main driver circuit 20 is changed from the high level to the low level when the input clock signal is changed from the low level to the high level.

Meanwhile, the gate of the NMOS transistor 32 in the sub-driver circuit 30 is directly supplied with the input clock signal. On the other hand, the gate of the PMOS transistor 31 is supplied with the output of the first control circuit section 41.

The first control circuit section 41 outputs a signal “a” in response to the input shown in FIG. 4. Namely, the first control circuit section 41 detects a falling edge (change from the high level to the low level) of the input clock signal to thereby change its output from the high level to the low level. The first control circuit section 41 then changes its output from the low level to the high level after the lapse of the predetermined time T2.

The sub-driver circuit 30 is supplied with the input clock signal and the signal “a”, and then when the input clock signal is changed from the high level to the low level, the sub-driver circuit 30 operates in a manner similar to the main driver 20 (operates in parallel concurrently) during the predetermined time T2. That is, After the predetermined time T2 lapses, the PMOS transistor 31 is turned on and the NMOS transistor 32 is turned off. When the predetermined time T2 lapses, the PMOS transistor 31 is turned off.

Meanwhile, when the input clock signal is changed from the low level to the high level, the sub-driver circuit 30 operates in a manner similar to the main driver 20 (operates in parallel concurrently) again. That is, the PMOS transistor 31 maintains the off-state while the NMOS transistor 32 is turned on.

The time of keeping the signal “a” at the low level (i.e., the predetermined time) can be adjusted by changing the number of the delay gates of the delay circuit 412 (illustrated in FIG. 3). The predetermined time T2 may be suitably adjusted to a pertinent time before the output of the main driver circuit 20 (namely, the output of the clock driver 10) reaches the high level. In this event, the output 1 of the clock driver 10 shows a waveform illustrated in FIG. 4. Thus, the output of the clock driver 10 has a steep rise-up edge without any overshoot, as shown in the waveform of the output 1 in FIG. 4.

In addition, a reference output in FIG. 4 shows an output signal waveform of the conventional clock driver circuit illustrated in FIG. 8.

As described above, in the configuration of the present embodiment, the sub-driver is turned off during a transient period from the low level to the high level of the output of the clock driver circuit 10. This shows that the driving capability di/dt of the clock driver circuit 10 thereafter can be decreased after the sub-driver 30 is turned off. Moreover, the overshoot in the output waveform, that would be caused to occur due to an inductor component of the circuit can be suppressed or prevented by the illustrated circuitry.

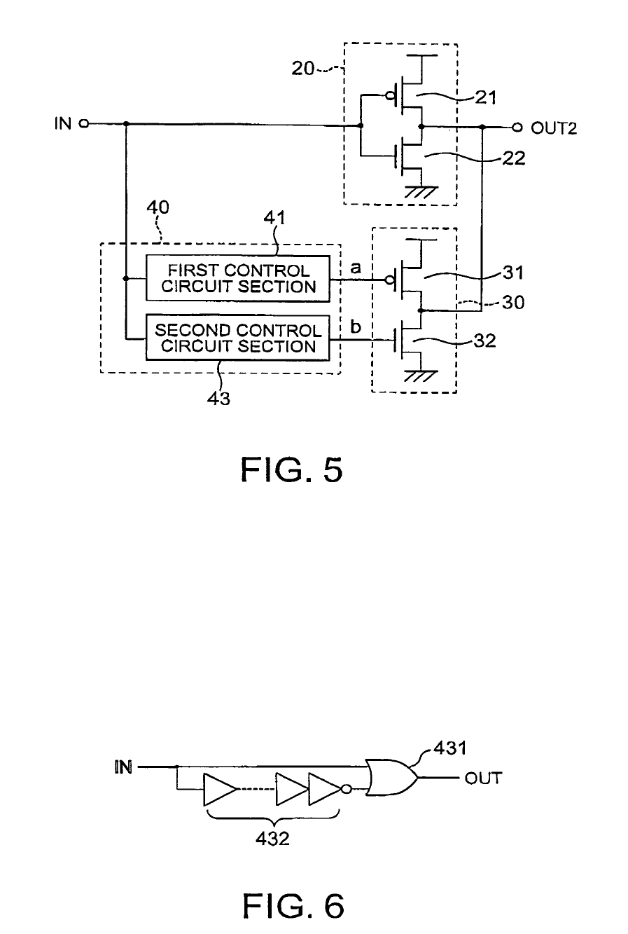

Next, a second embodiment of the present invention will be described by referring to FIGS. 5 through 7.

The clock driver circuit shown in FIG. 5 is different from that of the first embodiment in that the control circuit 40 has a second control circuit section 43.

The second control circuit section 43 is composed of a two-input AND gate 431 and a delay circuit 432 which is composed of a plurality of stages of the delay gates and the NOT gate, as shown in, for example, FIG. 6.

Referring to FIG. 5, the operation of the clock driver circuit will be described.

The main driver circuit 20 performs the same operation as that of the first embodiment.

The PMOS transistor 31 in the sub-driver circuit 30 also performs the same operation as that of the first embodiment.

The gate of the NMOS transistor 32 in the sub-driver circuit 30 is supplied with the output of the second control circuit section 43.

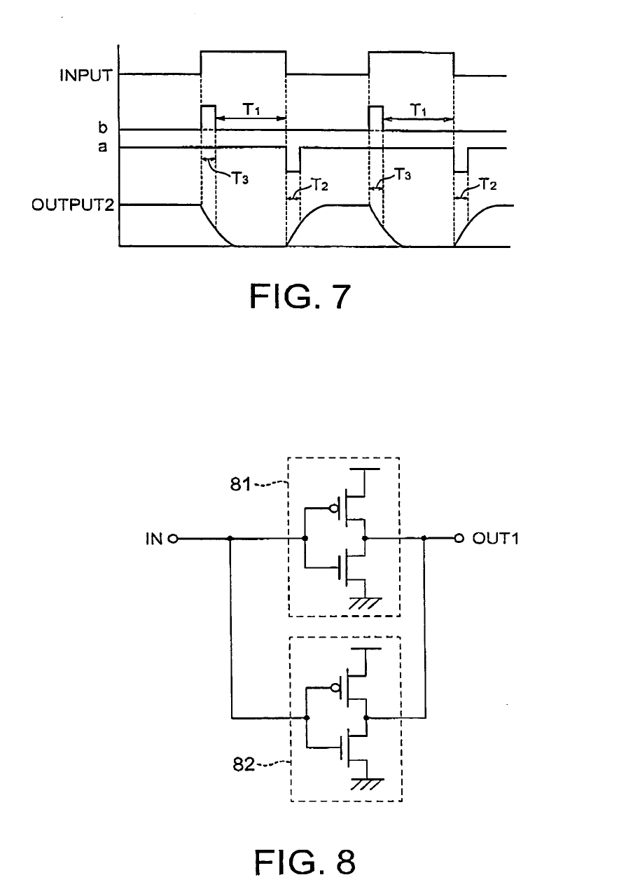

The second control circuit section 43 outputs a signal “b” in response to the input shown in FIG. 7. Namely, the second control circuit section 43 detects a rising edge of the input clock signal. The input clock signal changes from the low level to the high level at the rising edge. On detecting the rising edge, the output of the second control circuit section 43 changes from the low level to the high level. After lapse of a prescribed time T3, the second control circuit section 42 changes its output from the high level to the low level. It is to be noted here that the prescribed time T3 may be the same as or different from the predetermined time T2 set in the first control circuit section 41.

The NMOS transistor 32 in the sub-driver circuit 30 is supplied with the signal “b”, and then when the input clock signal is changed from the low level to the high level, the NMOS transistor 32 is turned on and keeps in the on-state for the prescribed time T3. Subsequently, when the prescribed time T3 lapses, the NMOS transistor 32 is turned off.

As a result, the sub-driver circuit 30 performs the operation similar to that of the main driver circuit 20 until the predetermined time T2 or the prescribed time T3 lapses from each of the rising edge and the falling edge of the input signal. On the other hand, the sub-driver circuit 30 stops its operation during other time periods T1 than the above-mentioned predetermined time T2 and prescribed time T3.

In the present embodiment as well, the time when the signal “b” rises to the high level (i.e., the prescribed time) can be adjusted by changing the number of the delay gates of the delay circuit. The prescribed time may be adjusted to an appropriate time before the output of the main driver circuit 20 (i.e., the output of the clock driver circuit 10) falls to the low level. This makes it possible to shape a waveform of an output 2 (FIG. 5) sent from the clock driver circuit 10 into a waveform shown in FIG. 7. As shown in the waveform of the output 2 in FIG. 5, the clock driver circuit 10 can remove both any overshoot and undershoot from the output 2.

As described above, according to the embodiment of the present embodiment, the sub-driver is turned off during the transient period of the output of the clock driver circuit 10 from the high level to the low level or the low level to the high level. This shows that the driving capability di/dt of the clock driver circuit 10 can be decreased after the turned off state of the sub-driver circuit 43. In addition, either the undershoot or the overshoot that might occur due to any inductor component in the output waveform can be suppressed or prevented.

What is claimed is:

1. A clock driver circuit comprising:
a plurality of driver circuits connected in parallel with each other; and
a control circuit for stopping the operation of a part of said plurality of driver circuits for a given period of time, in response to at least one of a rising edge and a falling edge of an input signal.

2. The clock driver circuit according to claim 1,
wherein said given period of time is set after a predetermined time lapses from the rising and/or the falling edges of said input signal.

3. The clock driver circuit according to claim 2, wherein said given period of time is determined by a time from a time point at which said predetermined time lapses from the falling edge of said input signal to the next rising edge of said input signal.

4. The clock driver circuit according to claim 2,
wherein said given period of time is determined by a time from a time point at which said predetermined time lapses from the rising edge of said input signal to the next falling edge of said input signal.

5. The clock driver circuit according to claim 1,
wherein each of said plurality of driver circuits is a CMOS inverter.

6. The clock driver circuit according to claim 3,
wherein each of said plurality of driver circuits is a CMOS inverter, and
wherein said control circuit comprises a circuit that is connected to a gate of a PMOS transistor of said part of the driver circuits, and that is specified by an OR output obtained by said input signal and a signal obtained by delaying said input signal for said predetermined time and by logically inverting said input signal.

7. The clock driver circuit according to claim 4,
wherein said driver circuit is a CMOS inverter circuit, and
wherein said control circuit comprises a circuit that is connected to a gate of an NMOS transistor of said part of the driver circuits, and that is specified by an AND output of said input signal and a signal obtained by delaying said input signal for said predetermined time and by logically inverting said input signal.

8. A driving method of a clock driver circuit comprising a plurality of driver circuits connected in parallel with each other, comprising:
stopping the operation of a part of said plurality of driver circuits for a given period of time, based on at least one of a rising edge and a falling edge of an input signal.

9. The driving method of the clock driver circuit according to claim 8,
wherein said given period of time is set after a predetermined time lapses from the rising and/or the falling edges of said input signal.

10. The driving method of the clock driver circuit according to claim 9,
wherein said given period of time is determined by a time from a time point at which said predetermined time lapses from the falling edge of said input signal to the next rising edge of said input signal.

11. The driving method of the clock driver circuit according to claim 9,
wherein said given period of time is determined by a time from a time point at which said predetermined time lapses from the rising edge of said input signal to the next falling edge of said input signal.
